(19) United States
(12) Patent Application Publication
(10) Pub. No.: US 2009/0168930 A1
(43) Pub. Date: Jul. 2, 2009

(54) Methods and Systems for Doppler Estimation and Adaptive Channel Filtering in a Communication System

(75) Inventors: Junqiang Li, Sunnyvale, CA (US); Baoguo Yang, San Jose, CA (US); Yue Chen, Fremont, CA (US)

Correspondence Address: Venture Pacific Law, PC, 5201 Great America Parkway, Suite 270, Santa Clara, CA, 95054, US

(73) Assignee: Augusta Technology, Inc., Santa Clara, CA (US)

(21) Appl. No.: 12/345,658

(22) Filed: Dec. 29, 2008

Related U.S. Application Data
(60) Provisional application No. 61/017,425, filed on Dec. 28, 2007.

(51) Int. Cl. H03D 1/04

(52) U.S. Cl. 375/346

(57) ABSTRACT

A method for Doppler shift estimation for channel estimation of a received signal, comprising the steps of: calculating time domain correlations; providing a Hamming window over the calculated time domain correlations; calculating a power spectrum by using FFT; calculating an adaptive threshold based on a noise floor and an average power density calculated from the power spectrum; and estimating a Doppler shift based on the adaptive threshold.

### CROSS REFERENCE

This application claims priority from a provisional patent application entitled “Doppler Estimation and Adaptive Channel Filtering in Time Domain” filed on Dec. 28, 2007 and having an Application No. 61/017,425. Said application is incorporated herein by reference.

### FIELD OF INVENTION

This invention relates to methods for channel estimation in data communications, and, in particular to, methods for Doppler shift estimation and adaptive channel filtering in a data communication system.

### BACKGROUND

Orthogonal frequency division multiplexing is a multi-carrier transmission technique that uses orthogonal subcarriers to transmit information within an available spectrum. Since the subcarriers may be orthogonal to one another, they may be spaced much more closely together within the available spectrum than, for example, the individual channels in a conventional frequency division multiplexing (FDM) system.

In an OFDM system, the subcarriers may be modulated with a low-rate data stream before transmission. It is advantageous to transmit a number of low-rate data streams in parallel instead of a single high-rate stream since low symbol rate schemes suffer less from intersymbol interference (ISI) caused by multipath propagation of the transmitted streams. For this reason, many modem digital communications systems are turning to the OFDM system as a modulation scheme for signals that need to survive in environments having multipath or strong interference. Many transmission standards have already adopted the OFDM system, including the IEEE 802.11a standard, the Digital Video Broadcasting—Handheld (DVB-H), the Digital Video Broadcasting Terrestrial (DVB-T), the Digital Audio Broadcast (DAB), and the Digital Television Broadcast (T-DMB).

Although the OFDM system is advantageous in combating intersymbol interference, it is quite sensitive to frequency deviations. The frequency deviations may be caused by the difference in the oscillator frequency of the receiver and the transmitter, or by the Doppler shift of the signal due to the movement of either the receiver or the transmitter. Frequency deviations cause significant interference between signals at different subcarriers, hence result in dramatic performance degradation. Therefore, channel estimation to correct the frequency deviations is critical for delivering good transmission quality.

Therefore, it is desirable to provide methods for estimating frequency deviations for a transmitted signal caused by a Doppler shift.

### SUMMARY OF INVENTION

An object of this invention is to provide methods for a power spectrum based Doppler estimation in a data communication system that can correctly estimate Doppler shifts to within 20 Hz at more than 95 percent probability.

Another object of this invention is to provide methods for channel estimation in a data communication system, where Doppler estimation and an adaptive channel filter in the time domain are used to improve performance.

Yet another object of this invention is to provide methods for Doppler estimation in a data communication system that is not sensitive to phase noise.

Briefly, a method for Doppler shift estimation for channel estimation of a received signal, comprising the steps of: calculating time domain correlations; providing a Hamming window over the calculated time domain correlations; calculating a power spectrum by using FFT; calculating an adaptive threshold based on a noise floor and an average power density calculated from the power spectrum; and estimating a Doppler shift based on the adaptive threshold.

An advantage of this invention is that Doppler shifts in a data communication system can be correctly estimated to within 20 Hz at more than 95 percent probability.

Another advantage of this invention is that performance is improved for channel estimation in a data communication system by using Doppler estimation and an adaptive channel filter in the time domain.

Yet another advantage of this invention is that methods for Doppler estimation in a data communication system that are not sensitive to phase noise are provided.

### DESCRIPTION OF THE DRAWINGS

The foregoing and other objects, aspects, and advantages of the invention will be better understood from the following detailed description of the preferred embodiment of the invention when taken in conjunction with the accompanying drawings in which:

FIG. 1 illustrates a flow chart of an embodiment of the present invention for Doppler estimation and adaptive channel filtering.

FIGS. 2a-2b illustrate a block diagram of an embodiment of the present invention for Doppler estimation and adaptive channel filtering.

FIG. 3 illustrates a block diagram of an embodiment of the present invention for calculating an adaptive threshold, then using the adaptive threshold for Doppler estimation.

FIGS. 4a-4c illustrate a flow chart of an embodiment of the present invention for an adaptive threshold based Doppler estimation.

### DETAILED DESCRIPTION OF THE PREFERRED EMBODIMENTS

The present invention will be described using a DVB-H system. However, it will be appreciated by one skilled in the art that the present invention can be applied to other communication systems.

### Channel Model

Due to the motion of a receiver or a transmitter, the frequency response of a DVB-H channel is a two-dimensional random process that can be characterized by a correlation function, H(f, t). The correlation function of the frequency response at different times and at different frequencies, r_{H}[k, m], can be expressed as the product of a time domain correlation, rₜ[m], and a frequency domain correlation, r_{f}[m], given in Equation (1) and Equation (2).

$$\begin{matrix}{r}_{H} [ k , m ] = E \{ H ( f + k Δ f , t + mT ) H * ( f , t ) \} \\ = {δ}_{h}^{2} {r}_{f} [ k ] {r}_{t} [ m ]\end{matrix} \qquad \begin{matrix}( 1 ) \\ ( 2 )\end{matrix}$$

where k is the carrier index, m is the symbol index, Δf is the subcarrier space, and T is the symbol time.

It is well known that the time domain correlation and the frequency domain correlation are related to a Doppler spread, f_{Dmax}, and a time delay spread, τₘₐₓ, respectively, in the following manner

rₜ[m]∝f_{Dmax} (3)

r_{f}[m]∝τₘₐₓ (4)

For example, in the typical urban 6-paths (TU6) channel model, the time domain correlation function and the frequency domain correlation function are zero-order Bessel functions, J₀(.).

In order to support estimating the Doppler value in RICE and AWGN spectrum channel models, it is not enough to consider only the time domain correlation. Thus, spectrum analysis is necessary for Doppler estimation in various spectrum channels.

### Doppler Estimation Algorithm

By transferring the time domain correlation function to the frequency domain by using a FFT, the channel power spectrum can be generated. Based on the power spectrum analysis, the Doppler bandwidth can be achieved. In various channel models including DVB-TU6, DVB-RA6, DAB-RA4, DAB-TU6 and self-defined 2-ray RICE channel model, a common feature is a sharp slope at the edge of the Doppler bandwidth (i.e. 10-20 dB higher than a noise floor). In a RICE channel model, the channel power spectrum can be shifted according to the frequency offset adjustment in a DVB-H receiver, such that the power spectrum may not be symmetrical, as would be in a DVB-TU6 channel model. Furthermore, if more than one Ray RICE channel has occurred, not only would the power spectrum be shifted, but the spectrum power at the frequency center for the different RICE channels may also have large variations due to channel fading.

According to these features, a novel power spectrum based on a Doppler estimation algorithm is proposed. By considering the implementation complexity and diversity gain, a total of ten equally spaced continual pilots for located sub-carriers are used for time domain correlation calculations. If a selected carrier is erased due to co-channel interference, then that carrier will not be used. Ten first-in-first-out (FIFO) buffers with a length of a 150 for each buffer are used for generating a correlation value. By considering the minimum 10 Hz or 20 Hz resolution Doppler bin in the 8K mode, 50 correlation values can be enough for Doppler estimation.

In order to smooth the noise floor in the high frequency range of the power spectrum, a Hamming window can be applied before a FFT is performed on the received signal. An adaptive threshold is calculated based on the noise floor and the average power density within a previously estimated Doppler bandwidth. Based on the adaptive threshold, the edge of the Doppler bandwidth can be clarified and estimated.

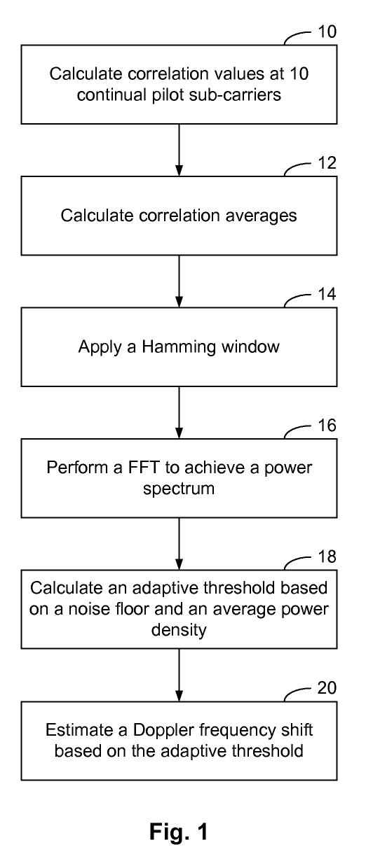

FIG. 1 illustrates a flow chart for an embodiment of the present invention for Doppler estimation and adaptive channel filtering. Referring to FIG. 1, correlation calculations are carried out with respect to the continual pilots (e.g. 10 pilots) for the subcarriers over a pre-defined number of symbols (e.g. 50 symbols) (10). Next, the correlation values are averaged over 10 continual pilot subcarriers (12) to generate (e.g. 50) average correlation values. The Hamming window can be added to the average correlation values with a pre-defined symbol offset (e.g. 0 to 49) (14). A FFT is then performed over the Hamming window correlation values to achieve a power spectrum for the channel response (16).

An adaptive threshold is then selected based on a noise floor and an average power density based on the FFT of the received signal within the previous Doppler estimation (18), where the initial Doppler value can be a pre-defined number. Finally, the Doppler estimation based on the adaptive threshold is performed (20).

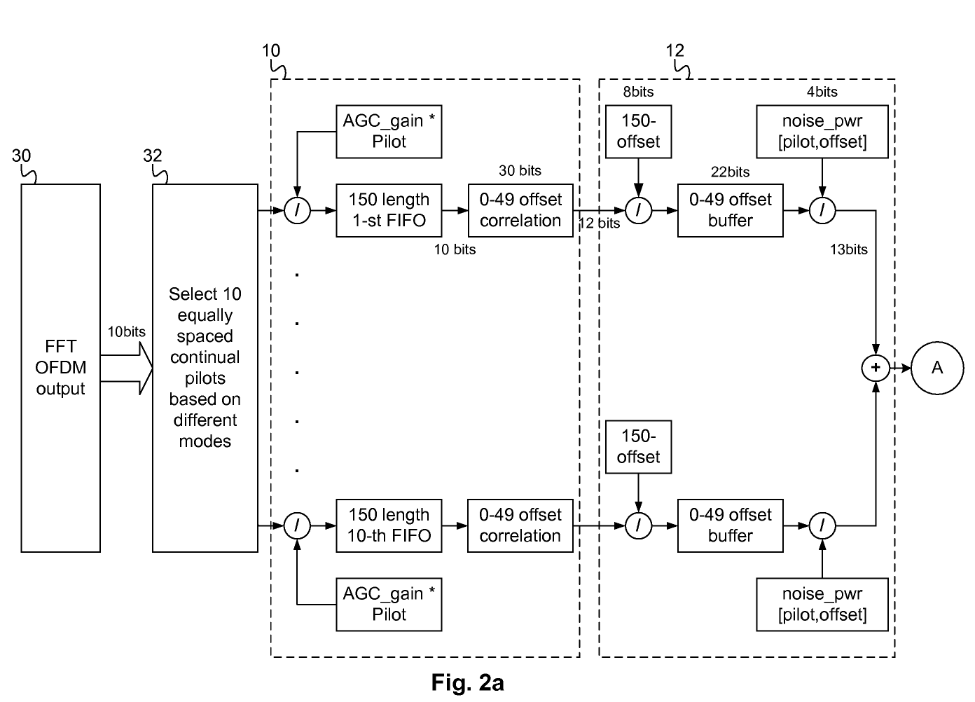

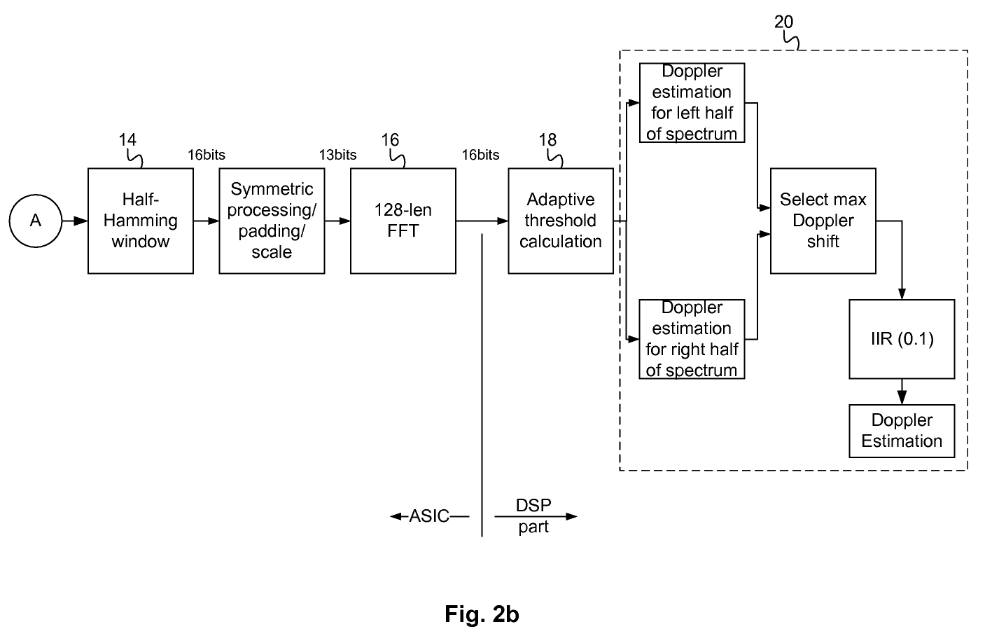

FIGS. 2a-2b illustrate a block diagram of an embodiment of the present invention for Doppler estimation and adaptive channel filtering. A FFT is applied to a received signal (30). Next, ten equally spaced continual pilots for located sub-carriers can be selected for time domain correlation calculations (32). If a selected carrier is erased due to co-channel interference, then that carrier will not be used. Ten FIFO buffers are used for generating a correlation value (10). By considering the minimum 10 Hz or 20 Hz resolution Doppler bin in 8K mode, 50 correlation values can be enough for Doppler estimation (12). In order to smooth the noise floor in the high frequency range of the power spectrum, a Hamming window is applied (14) before the FFT is performed (16). An adaptive threshold is calculated based on the noise floor and the average power density within the previously estimated Doppler bandwidth (18). Based on the adaptive threshold, the edge of Doppler bandwidth can be clarified (20).

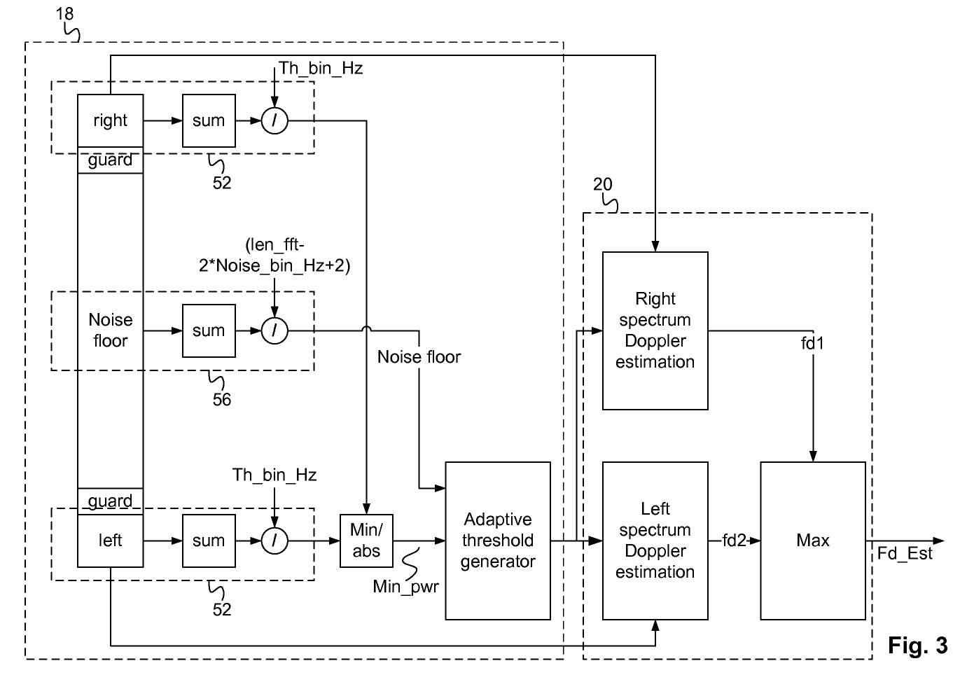

FIG. 3 illustrates a block diagram of an embodiment of the present invention for calculating an adaptive threshold, then using the adaptive threshold for Doppler estimation. First, an adaptive threshold is calculated based on a noise floor and an average power density (18). In doing so, an average power density can be calculated by finding the minimum of a left part average power (52) and a right part average power (52). Next, a noise floor is calculated (56). The average power density and the noise floor can then be used by the adaptive threshold generator to calculate an adaptive threshold.

The Doppler estimation can then be performed using the adaptive threshold (20). In particular, the adaptive threshold is used for a right spectrum Doppler estimation and a left spectrum Doppler estimation. The maximum of which is outputted, Fd_est.

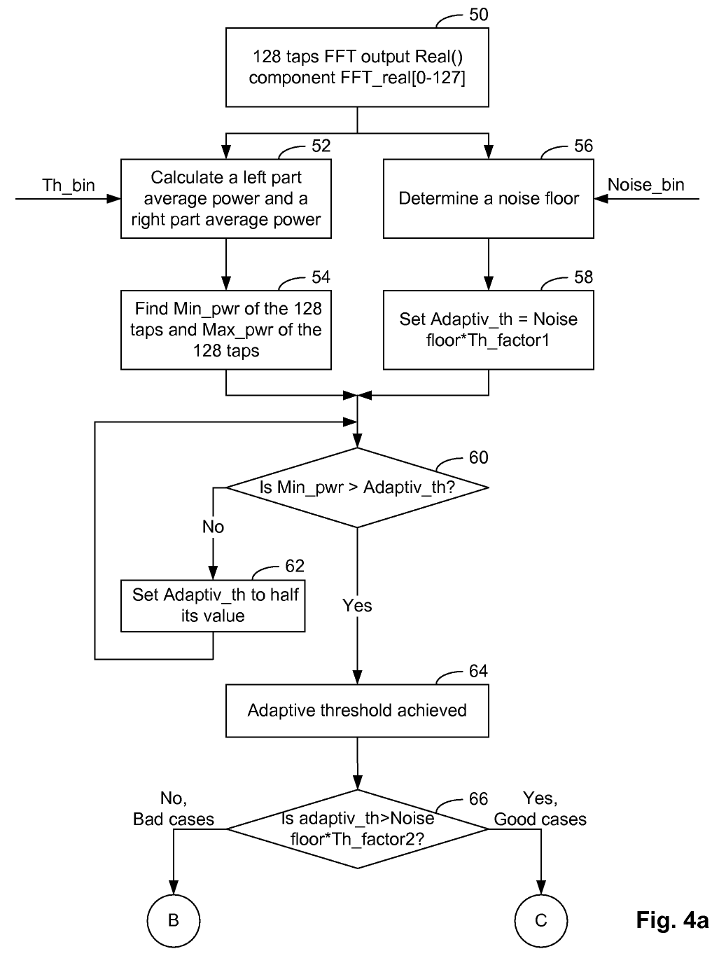

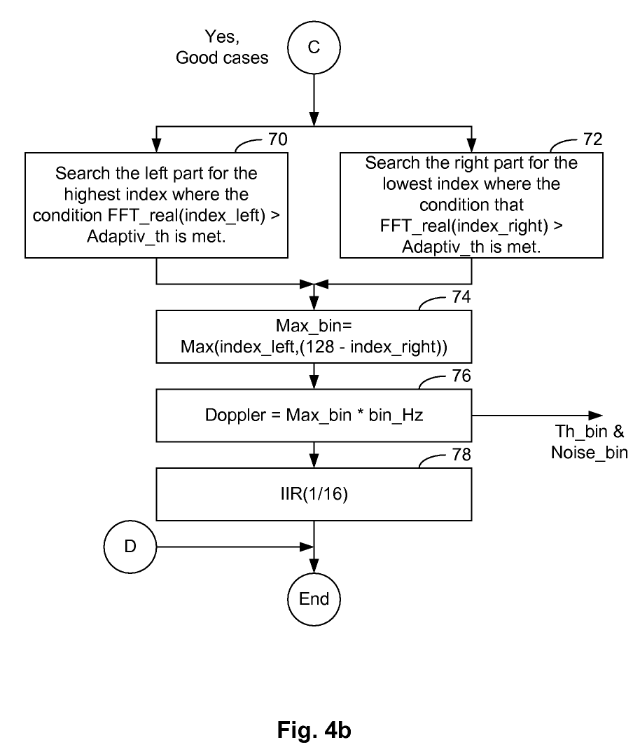

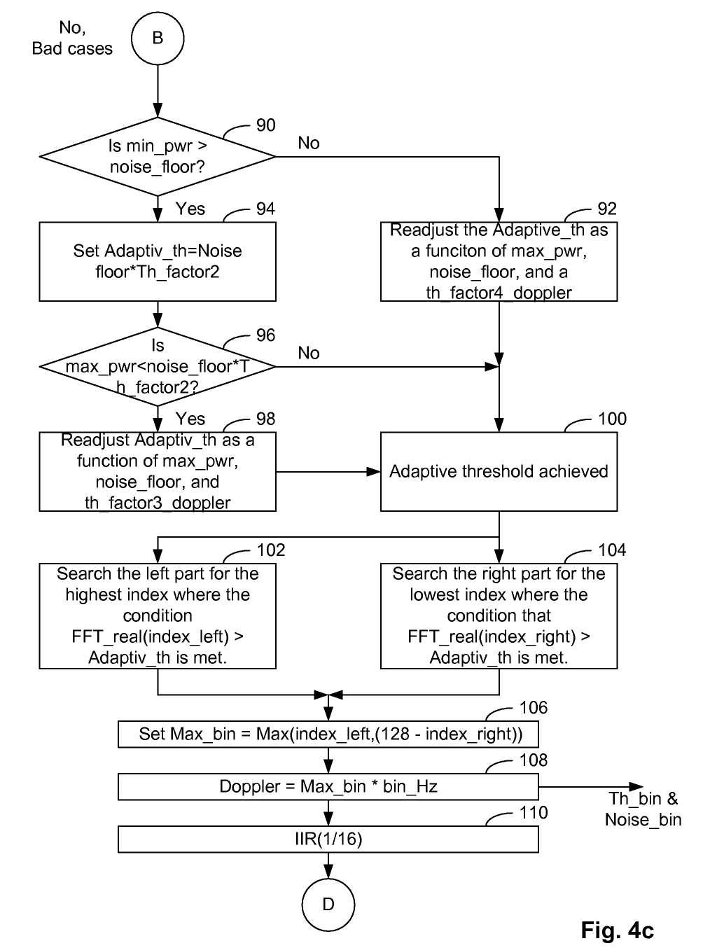

FIGS. 4a-4c illustrate a flow chart for an embodiment of the present invention for an adaptive threshold based Doppler estimation. In the first step, a FFT is applied to 128 taps for a received signal, where the output of the FFT can be divided into a left part (negative frequency component) and a right part (positive frequency component). Since the power values of the received signal are of concern, the real values of the received signal are analyzed (50). A left part average power and a part right average power can then be calculated (52). FIG. 3 illustrates finding the left power average by summing the left part, then dividing by a Th_bin_Hz (52). The right part power average is calculated by summing the right part, then dividing by the Th_bin_Hz (52). Referring to FIG. 4a, a minimum power value (referred to as min_pwr) can be determined by finding the minimum power of the respective powers for the 128 taps (54). A maximum power value (referred to as max_pwr) can be determined by finding the maximum power of the respective powers for the 128 taps (54).

A noise floor can also be found for the received signal (56). FIG. 3 illustrates the calculation of the noise floor by summing the noise floor, then dividing by a value equaled to the length of the FFT of the received signal (len_fft) minus 2 times a Noise_bin_Hz value plus 2 (56). Referring back to FIG. 4a, an adaptive threshold (Adaptive_th) is calculated (58) in Equation (5) by multiplying the noise floor by a first threshold factor (Th_factor1), wherein in the preferred embodiment Th_factor1 is equal to 10.

Adaptiv_th=Noise_floor*Th_factor1 (5)

The threshold factors used in FIG. 4 can be found through bit error rate and Doppler estimation accuracy simulations, where the accuracy can be compared with a histogram of the estimation results paired with the actual Doppler shifts and then adjusted accordingly.

If the minimum power value is not greater than the adaptive threshold (Apaptive_th) (60), the Adaptiv_th can be halved to lower such Adaptive_th (62). If the minimum power value is greater than the Adaptive_th, the adaptive threshold is achieved (64).

If the adaptive threshold is greater than the noise floor multiplied by a second threshold factor (Th_factor2) (66), referred to as the good cases, a highest index on the left part (indices from 0 to 63), denoted index_left, where a condition that the FFT_real of the index_left is greater than the Adaptive_th is met, can be found (70). A lowest index on the right side (indices from 64 to 127), denoted index right, where the condition that the FFT_real of the index right is greater than the Adaptive_th, can also be found (72).

Next, the index_left and 128 minus the index right are compared by finding the maximum value, denoted Max_Bin (74). Max_bin corresponds to the Doppler shift. Since this is just an index, the Max_bin can be multiplied with the bin_Hz (the width of the bin) to get the Doppler shift (76). The Th_bin can be generated based on the Max_bin with some protection gap and can be fed back to calculate the left part average power and the right part average power (52). The Noise_bin can then be generated based on the noise, and be fed back to determine a noise floor (56). An infinite impulse response (IIR) filter is then applied for monitoring purposes, where 1/16 is the IIR factor (78).

If the adaptive threshold is not greater than the noise floor (noise_floor) multiplied by a second threshold factor (Th_factor2), referred to as the bad cases, and if the minimum power (min_pwr) is not greater than the noise_floor (90), the Adaptive_th is readjusted as a function of the max_pwr, the noise_floor, and a th_factor4_doppler (92) in accordance with Equation (6).

Adaptive_{—}th=MAX(Floor(max_pwr*3/32),Floor(noise_floor*th_factor4_doppler)) (6)

If the minimum power (min_pwr) is greater than the noise_floor (90), the Adaptive_th is set to the noise_floor multiplied by Th_factor2 (94). If the maximum power is less than the noise_floor multiplied by Th_factor2 (96), the Adaptive_th is readjusted as a function of the max_pwr, the noise_floor, and a th_factor3_doppler (98), according to Equation (7); else, the Adaptive_th is achieved (100).

Adaptiv_{—}th=MAX((int)(max_pwr*3/32),(int)(noise_floor*th_factor3_doppler) (7)

Then, similarly to the good cases, a maximum (or highest) index on the left side (indices from 0 to 63), where FFT real is greater than the Adaptive_th, is located (102). A minimum index on the right side (indices from 64 to 127), where FFT_real is greater than the Adaptive_th, is also located (104). Then, an overall max, Max_bin, the Doppler shift, and the IIR are calculated (along with Th_bin and Noise_bin) (106, 108, and 110, respectively).

While the present invention has been described with reference to certain preferred embodiments or methods, it is to be understood that the present invention is not limited to such specific embodiments or methods. Rather, it is the inventor's contention that the invention be understood and construed in its broadest meaning as reflected by the following claims. Thus, these claims are to be understood as incorporating not only the preferred methods described herein but all those other and further alterations and modifications as would be apparent to those of ordinary skilled in the art.

We claim:

1. A method for Doppler shift estimation for channel estimation of a received signal, comprising the steps of:
calculating time domain correlations;
providing a Hamming window over the calculated time domain correlations;
calculating a power spectrum by using FFT;
calculating an adaptive threshold based on a noise floor and an average power density calculated from the power spectrum; and
estimating a Doppler shift based on the adaptive threshold.

2. The method of claim 1 wherein an average Doppler shift is calculated after the estimating step.

3. The method of claim 1 in the calculating the time domain correlations step, wherein a first pre-defined number of equally spaced continual pilots for located subcarriers are used to calculate the time domain correlations over a second pre-defined number of symbols.

4. The method of claim 3 wherein after the calculating the time domain correlations step and before the providing step, further comprising a step of, averaging said correlation values over the first pre-defined number of continual pilot subcarriers.

5. The method of claim 1 in the calculating the adaptive threshold step, wherein said adaptive threshold is adjusted based on a minimum power value.

6. The method of claim 1 in the calculating the adaptive threshold step, wherein said adaptive threshold is adjusted based on a maximum power value.

7. The method of claim 1 wherein in the calculating an adaptive threshold step, further comprising the substeps of:
defining a left part and a right part of a plurality of taps of the received signal;
determining a noise floor as a function of a noise bin;
setting the adaptive threshold as a function of the noise floor and a first threshold factor;
calculating a left average power and a right average power;
determining a minimum power from the plurality of taps;
determining a maximum power from the plurality of taps; and
while the minimum power is less than the adaptive threshold, setting the adaptive threshold to one-half of the value of the adaptive threshold.

8. The method of claim 7 wherein in the estimating Doppler shift step, further comprising the substeps of:
if the adaptive threshold is greater than the noise floor multiplying a second threshold factor,
determining the highest index of the taps in the left part having power greater than the adaptive threshold;
determining the lowest index of the taps in the right part having power greater than the adaptive threshold;
determining a maximum bin as a function of the power of the tap having the highest index and the power of the tap having the lower index; and
determining the Doppler shift as a function of the maximum bin.

9. The method of claim 7 wherein in the estimating Doppler shift step, further comprising the substeps of:
if the adaptive threshold is not greater than the noise floor multiplying a second threshold factor,
if the minimum power is greater than the noise floor,
setting the adaptive threshold as a function of the noise floor and the second threshold factor; and
if the maximum power is less than a function of the noise floor and
the second threshold factor, adjusting the adaptive threshold as a function of the maximum power, the noise floor, and a third threshold factor;
if the minimum power is not greater than the noise floor, adjusting the adaptive threshold as a function of the maximum power, the noise floor, and a fourth threshold factor;
determining the highest index of the taps in the left part having power greater than the adaptive threshold;
determining the lowest index of the taps in the right part having power greater than the adaptive threshold;
determining a maximum bin as a function of the power of the tap having the highest index and the power of the tap having the lower index; and
determining the Doppler shift as a function of the maximum bin.

10. The method of claim 8 wherein in the estimating Doppler shift step, further comprising the substeps of:
if the adaptive threshold is not greater than the noise floor multiplying a second threshold factor,
if the minimum power is greater than the noise floor,
setting the adaptive threshold as a function of the noise floor and the second threshold factor; and
if the maximum power is less than a function of the noise floor and
the second threshold factor, adjusting the adaptive threshold as a function of the maximum power, the noise floor, and a third threshold factor;
if the minimum power is not greater than the noise floor, adjusting the adaptive threshold as a function of the maximum power, the noise floor, and a fourth threshold factor;
determining the highest index of the taps in the left part having power greater than the adaptive threshold;
determining the lowest index of the taps in the right part having power greater than the adaptive threshold;
determining a maximum bin as a function of the power of the tap having the highest index and the power of the tap having the lower index; and
determining the Doppler shift as a function of the maximum bin.

11. A method for Doppler shift estimation for channel estimation of a received signal, comprising the steps of:
calculating time domain correlations, wherein a first pre-defined number of equally spaced continual pilots for located subcarriers are used to calculate the time domain correlations over a second pre-defined number of symbols;
providing a Hamming window over the calculated time domain correlations;
calculating a power spectrum by using FFT;
calculating an adaptive threshold based on a noise floor and an average power density calculated from the power spectrum;
estimating a Doppler shift based on the adaptive threshold; and
calculating an average Doppler shift.

12. The method of claim 11 wherein after the calculating the time domain correlations step and before the providing step, further comprising a step of, averaging said correlation values over the first pre-defined number of continual pilot subcarriers.

13. The method of claim 11 in the calculating the adaptive threshold step, wherein said adaptive threshold is adjusted based on a minimum power value.

14. The method of claim 13 in the calculating the adaptive threshold step, wherein said adaptive threshold is adjusted based on a maximum power value.

15. The method of claim 11 wherein in the calculating an adaptive threshold step, further comprising the substeps of:
defining a left part and a right part of a plurality of taps of the received signal;
determining a noise floor as a function of a noise bin;
setting the adaptive threshold as a function of the noise floor and a first threshold factor;
calculating a left average power and a right average power;
determining a minimum power from the plurality of taps;
determining a maximum power from the plurality of taps; and
while the minimum power is less than the adaptive threshold, setting the adaptive threshold to one-half of the value of the adaptive threshold.

16. The method of claim 15 wherein in the estimating Doppler shift step, further comprising the substeps of:
if the adaptive threshold is greater than the noise floor multiplying a second threshold factor,
determining the highest index of the taps in the left part having power greater than the adaptive threshold;
determining the lowest index of the taps in the right part having power greater than the adaptive threshold;
determining a maximum bin as a function of the power of the tap having the highest index and the power of the tap having the lower index; and
determining the Doppler shift as a function of the maximum bin.

17. The method of claim 15 wherein in the estimating Doppler shift step, further comprising the substeps of:
if the adaptive threshold is not greater than the noise floor multiplying a second threshold factor,
if the minimum power is greater than the noise floor,
setting the adaptive threshold as a function of the noise floor and the second threshold factor; and
if the maximum power is less than a function of the noise floor and
the second threshold factor, adjusting the adaptive threshold as a function of the maximum power, the noise floor, and a third threshold factor;
if the minimum power is not greater than the noise floor, adjusting the adaptive threshold as a function of the maximum power, the noise floor, and a fourth threshold factor;
determining the highest index of the taps in the left part having power greater than the adaptive threshold;
determining the lowest index of the taps in the right part having power greater than the adaptive threshold;
determining a maximum bin as a function of the power of the tap having the highest index and the power of the tap having the lower index; and
determining the Doppler shift as a function of the maximum bin.

18. The method of claim 16 wherein in the estimating Doppler shift step, further comprising the substeps of:
if the adaptive threshold is not greater than the noise floor multiplying a second threshold factor,
if the minimum power is greater than the noise floor,
setting the adaptive threshold as a function of the noise floor and the second threshold factor; and
if the maximum power is less than a function of the noise floor and
the second threshold factor, adjusting the adaptive threshold as a function of the maximum power, the noise floor, and a third threshold factor;
if the minimum power is not greater than the noise floor, adjusting the adaptive threshold as a function of the maximum power, the noise floor, and a fourth threshold factor;
determining the highest index of the taps in the left part having power greater than the adaptive threshold;
determining the lowest index of the taps in the right part having power greater than the adaptive threshold;
determining a maximum bin as a function of the power of the tap having the highest index and the power of the tap having the lower index; and
determining the Doppler shift as a function of the maximum bin.

19. A method for Doppler shift estimation for channel estimation of a received signal, comprising the steps of:
calculating time domain correlations, wherein a first pre-defined number of equally spaced continual pilots for located subcarriers are used to calculate the time domain correlations over a second pre-defined number of symbols;
averaging said correlation values over the first pre-defined number of continual pilot subcarriers;
providing a Hamming window over the calculated time domain correlations;
calculating a power spectrum by using FFT;
calculating an adaptive threshold based on a noise floor and an average power density calculated from the power spectrum, comprising the substeps of:
defining a left part and a right part of a plurality of taps of the received signal;
determining a noise floor as a function of a noise bin;
setting the adaptive threshold as a function of the noise floor and a first threshold factor;
calculating a left average power and a right average power;
determining a minimum power from the plurality of taps;
determining a maximum power from the plurality of taps; and
while the minimum power is less than the adaptive threshold, setting the adaptive threshold to one-half of the value of the adaptive threshold;
estimating a Doppler shift based on the adaptive threshold, comprising the substeps of:
if the adaptive threshold is greater than the noise floor multiplying a second threshold factor,
determining the highest index of the taps in the left part having power greater than the adaptive threshold;
determining the lowest index of the taps in the right part having power greater than the adaptive threshold;
determining a maximum bin as a function of the power of the tap having the highest index and the power of the tap having the lower index; and
determining the Doppler shift as a function of the maximum bin;
if the adaptive threshold is not greater than the noise floor multiplying a second threshold factor,
if the minimum power is greater than the noise floor,
setting the adaptive threshold as a function of the noise floor and the second threshold factor; and
if the maximum power is less than a function of the noise
floor and the second threshold factor, adjusting the adaptive
threshold as a function of the maximum power, the noise floor, and
a third threshold factor;
if the minimum power is not greater than the noise floor, adjusting
the adaptive threshold as a function of the maximum power, the noise floor, and a fourth threshold factor;
determining the highest index of the taps in the left part having power greater than the adaptive threshold;
determining the lowest index of the taps in the right part having power greater than the adaptive threshold;
determining a maximum bin as a function of the power of the tap having the highest index and the power of the tap having the lower index; and
determining the Doppler shift as a function of the maximum bin; and calculating an average Doppler shift.
